(19) United States
(12) Patent Application Publication
(10) Pub. No.: US 2010/0176412 A1
(43) Pub. Date: Jul. 15, 2010

(54) ORGANIC EL DEVICE AND METHOD OF MANUFACTURING THE SAME

(76) Inventors: Shuhei Yokoyama, Ishikawa-gun (JP); Masuyuki Oota, Hakusan-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/683,603

(22) Filed: Jan. 7, 2010

(30) Foreign Application Priority Data
Jan. 14, 2009 (JP) 2009-005927

(51) Int. Cl. H01L 51/54; H01L 21/30

(52) U.S. Cl. 257/98; 438/29; 257/40; 257/E51.018; 257/E21.211

(57) ABSTRACT

An organic EL device includes an insulative film, a first pixel electrode and a second pixel electrode which are disposed on the insulative film, a first light emission layer which is commonly disposed above the first pixel electrode and the second pixel electrode, a second light emission layer which is disposed above the first light emission layer, a counter-electrode which is disposed above the second light emission layer, and an exciton block layer which is disposed between the first light emission layer and the second light emission layer.

### CROSS-REFERENCE TO RELATED APPLICATIONS

This application is based upon and claims the benefit of priority from prior Japanese Patent Application No. 2009-005927, filed Jan. 14, 2009, the entire contents of which are incorporated herein by reference.

### BACKGROUND OF THE INVENTION

1. Field of the Invention

The present invention relates to an organic electroluminescence (EL) device, and a method of manufacturing the same.

2. Description of the Related Art

In recent years, display devices using organic electroluminescence (EL) elements have vigorously been developed, by virtue of their features of self-emission, a high response speed, a wide viewing angle, a high contrast, small thickness and light weight.

In the organic EL element, holes are injected from a hole injection electrode (anode), electrons are injected from an electron injection electrode (cathode), and the holes and electrons are recombined in a light emitting layer, thereby producing light. In order to obtain full-color display, it is necessary to form pixels which emit red (R) light, green (G) light and blue (B) light, respectively. It is necessary to selectively apply light-emitting materials, which emit lights with different light emission spectra, such as red, green and blue, to light-emitting layers of organic EL elements which constitute the red, green and blue pixels. As a method for selectively applying such light-emitting materials, there is known a vacuum evaporation method. In the case of forming films of low-molecular-weight organic EL materials by such a vacuum evaporation method, there is a method in which mask evaporation is performed independently for respective color pixels by using a metallic fine mask having openings in association with the respective color pixels (see, e.g. Jpn. Pat. Appin. KOKAI Publication No. 2003-157973).

In the mask evaporation method using the metallic fine mask, however, pixels become very fine in the case where a high fineness (resolution) is required for the display device. As a result, a so-called color mixture defect, by which light-emitting materials of respective colors are mixed, occurs frequently, and full-color display with high fineness is difficult realize.

On the other hand, there is disclosed an organic EL element which is configured such that a hole prevention layer, an electron prevention layer and an exciton prevention layer, which are in contact with the light emitting layer, include metal complex compounds of specific structures (see, e.g. Jpn. Pat. Appin. KOKAI Publication No. 2008-147424).

### BRIEF SUMMARY OF THE INVENTION

According to an aspect of the present invention, there is provided an organic EL device comprising: an insulative film; first to third pixel electrodes disposed on the insulative film; a first light emission layer which includes a first dopant material and is commonly disposed above the first to third organic pixel electrodes; a second light emission layer which includes a second dopant material and is disposed above the first light emission layer; a third light emission layer which includes a third dopant material and is disposed above the second light emission layer; a counter-electrode which is disposed above the third light emission layer; and an exciton block layer which is disposed at least between the first light emission layer and the second light emission layer or between the second light emission layer and the third light emission layer, wherein an emission light color between the first pixel electrode and the counter-electrode, an emission light color between the second pixel electrode and the counter-electrode and an emission light color between the third pixel electrode and the counter-electrode are different from each other.

According to another aspect of the present invention, there is provided an organic EL device comprising: an insulative film; a first pixel electrode and a second pixel electrode which are disposed on the insulative film; a first light emission layer which is commonly disposed above the first pixel electrode and the second pixel electrode; a second light emission layer which is disposed above the first light emission layer; a counter-electrode which is disposed above the second light emission layer; and an exciton block layer which is disposed between the first light emission layer and the second light emission layer.

According to another aspect of the present invention, there is provided a method of manufacturing an organic EL device comprising: forming a first pixel electrode and a second pixel electrode on an insulative film; forming a first light emission layer commonly above the first pixel electrode and the second pixel electrode; forming an exciton block layer above the first light emission layer; forming a second light emission layer above the exciton block layer; and forming a counter-electrode above the second light emission layer.

According to another aspect of the present invention, there is provided a method of manufacturing an organic EL device comprising: forming first to third pixel electrodes on an insulative film; forming a first light emission layer commonly above the first to third pixel electrodes; forming a second light emission layer above the first light emission layer; forming a third light emission layer above the second light emission layer; forming a counter-electrode above the third light emission layer; and forming an exciton block layer at least between the first light emission layer and the second light emission layer or between the second light emission layer and the third light emission layer.

### BRIEF DESCRIPTION OF THE SEVERAL VIEWS OF THE DRAWING

FIG. 1 is a cross-sectional view which schematically shows an example of the structure which is adoptable in an organic EL display device according to an embodiment of the present invention;

FIG. 2 schematically shows an example of the structure which is adoptable in first to third organic EL elements which are included in the organic EL display device shown in FIG. 1;

FIG. 3 is a cross-sectional view of a display panel including the first to third organic EL elements shown in FIG. 2;

FIG. 4 is a view for explaining the relationship in energy level between respective layers in organic layers of the first to third EL elements shown in FIG. 2;

FIG. 5 is a flow chart for explaining a method for manufacturing the first to third organic EL elements shown in FIG. 2;

FIG. 6 is a view for explaining exposure steps PHOTO1 and PHOTO2 shown in FIG. 5;

FIG. 7 is a flow chart for explaining another method for manufacturing the first to third organic EL elements shown in FIG. 2;

FIG. 8 is a graph for explaining optical quenching in light emission layers;

FIG. 9 schematically shows another example of the structure which is adoptable in the display panel shown in FIG. 1;

FIG. 10 is a flow chart for explaining a method for manufacturing first to third organic EL elements shown in FIG. 9;

FIG. 11 is a flow chart for explaining another method for manufacturing the first to third organic EL elements shown in FIG. 9;

FIG. 12 schematically shows another example of the structure which is adoptable in the display panel shown in FIG. 1;

FIG. 13 is a flow chart for explaining a method for manufacturing the first to third organic EL elements shown in FIG. 12;

FIG. 14 is a flow chart for explaining another method for manufacturing the first to third organic EL elements shown in FIG. 12; and

FIG. 15 is a view for explaining another example of the exposure steps PHOTO1 and PHOTO2.

### DETAILED DESCRIPTION OF THE INVENTION

An embodiment of the present invention will now be described in detail with reference to the accompanying drawings. In the drawings, structural elements having the same or similar functions are denoted by like reference numerals, and an overlapping description is omitted.

In the present embodiment, as an example of the organic EL device, a description is given of an organic EL display device which adopts an active matrix driving method.

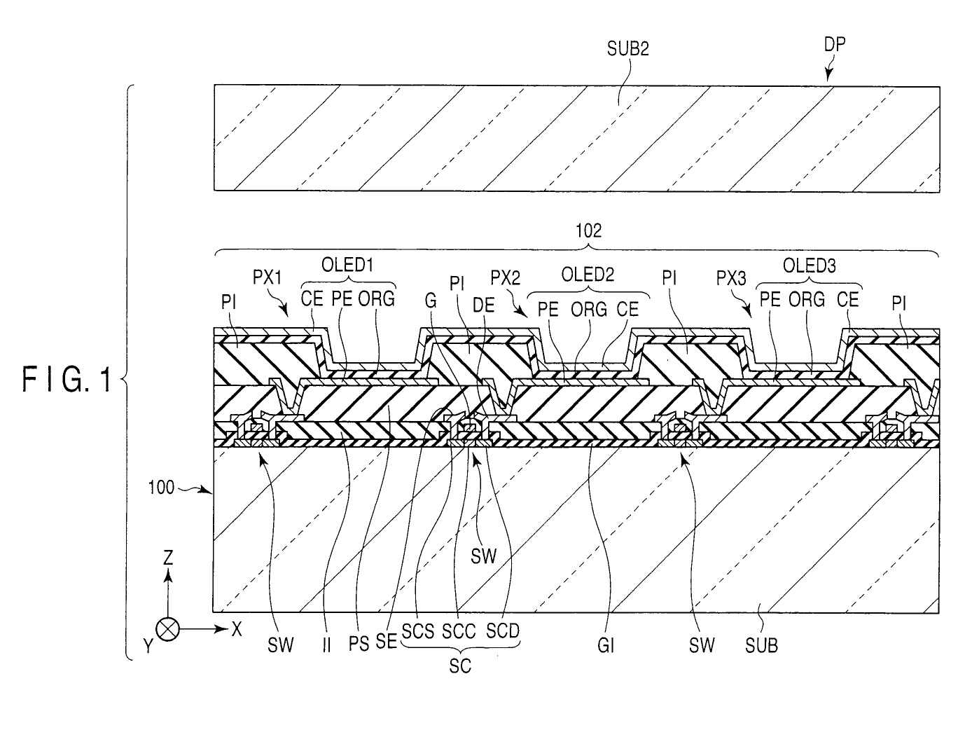

FIG. 1 is a cross-sectional structure of a display panel DP which includes switching elements SW and first to third organic EL elements OLED1 to OLED3 of the organic EL display device according to the embodiment. Each of the first to third organic EL elements OLED1 to OLED3 is of a top emission type in which light is radiated from the side of a counter-substrate SUB2. In the embodiment, however, each of the first to third organic EL elements OLED1 to OLED3 may be of a bottom emission type in which light is radiated from the side of an array substrate 100.

The array substrate 100 includes an insulative substrate SUB having light transmissivity, such as a glass substrate or a plastic substrate. The switching elements SW and first to third organic EL elements OLED1 to OLED3 are disposed above the insulative substrate SUB in an active area 102 for displaying an image.

A semiconductor layer SC of the switching element SW is disposed on the insulative substrate SUB. The semiconductor layer SC is formed of, e.g. polysilicon. In the semiconductor layer SC, a source region SCS and a drain region SCD are formed, with a channel region SCC being interposed.

A gate insulation film GI is formed on the semiconductor layer SC. The gate insulation film GI extends over almost the entirety of the active area 102. The gate insulation film GI is formed of an inorganic compound such as tetraethyl orthosilicate (TEOS), silicon oxide or silicon nitride.

A gate electrode G of the switching element SW is disposed on the gate insulation film GI immediately above the channel region SCC. In this example, the switching element SW is a top-gate-type p-channel thin-film transistor (TFT). An interlayer insulation film II is formed on the gate electrode G. The interlayer insulation film II is also disposed on the gate insulation film GI. The interlayer insulation film II extends over almost the entirety of the active area 102. The interlayer insulation film II is formed of an inorganic compound such as silicon oxide or silicon nitride.

A source electrode SE and a drain electrode DE of the switching element SW are disposed on the interlayer insulation film II. The source electrode SE is put in contact with the source region SCS of the semiconductor layer SC. The drain electrode DE is put in contact with the drain region SCD of the semiconductor layer SC. The gate electrode G, source electrode SE and drain electrode DE of the switching element SW are formed by using an electrically conductive material, such as molybdenum (Mo), tungsten (W), aluminum (Al) or titanium (Ti).

A passivation film PS is formed on the source electrode SE and drain electrode DE. The passivation film PS is also disposed on the interlayer insulation film II. The passivation film PS extends over almost the entirety of the active area 102. The passivation film PS is formed of, e.g. silicon nitride (SiNx), or an organic compound such as an ultraviolet-curing resin or a thermosetting resin.

Pixel electrodes PE, which constitute the first to third organic EL elements OLED1 to OLED3, are disposed on the passivation film PS. The passivation film PS corresponds to an insulative film which becomes an underlying layer of the pixel electrodes PE. Each pixel electrode PE of the first to third organic EL elements OLED1 to OLED3 is electrically connected to the drain electrode DE of the switching element SW. The pixel electrode PE corresponds to, for example, an anode.

A partition wall PI is disposed on the passivation film PS. The partition wall PI is disposed, for example, in a lattice shape in a manner to surround the entire periphery of the pixel electrode PE. The partition wall PI may be disposed in a stripe shape extending in a Y direction between the pixel electrodes PE. The partition wall PI is, for example, an organic insulation layer. The partition wall PI can be formed, for example, by using a photolithography technique.

An organic layer ORG, which constitutes the first to third organic EL elements OLED1 to OLED3, is disposed on each pixel electrode PE. The organic layer ORG is a continuous film which extends over almost the entirety of the active area 102 including all pixels PX1 to PX3, and the organic layer ORG extends over the first to third organic EL elements OLED1 to OLED3. Specifically, the organic layer ORG covers the pixel electrodes PE and partition wall PI. The details will be described later.

A counter-electrode CE, which constitutes the first to third organic EL elements OLED1 to OLED3, is disposed on the organic layer ORG. In this example, the counter-electrode CE corresponds to a cathode. The counter-electrode CE is a continuous film which extends over almost the entirety of the active area 102 including all pixels PX1 to PX3, and the counter-electrode CE extends over the first to third organic EL elements OLED1 to OLED3. In short, the counter-electrode CE covers the organic layer ORG. The counter-electrode CE is a common electrode which is shared by the first to third organic EL elements OLED1 to OLED3.

The pixel electrodes PE, organic layer ORG and counter-electrode CE constitute first to third organic EL elements OLED1 to OLED3 which are disposed in association with the pixels PX1 to PX3.

Specifically, the pixel PX1 includes the first organic EL element OLED1, the pixel PX2 includes the second organic EL element OLED2, and the pixel PX3 includes the third organic EL element OLED3. Although FIG. 1 shows one first organic EL element OLED1 of the pixel PX1, one second organic EL element OLED2 of the pixel PX2 and one third organic EL element OLED3 of the pixel PX3, these organic EL elements OLED1, OLED2 and OLED3 are repeatedly disposed in an X direction. Specifically, another first organic EL element OLED1 is disposed adjacent to the third organic EL element OLED3 that is shown on the right side part of FIG. 1. Similarly, another third organic EL element OLED3 is disposed adjacent to the first organic EL element OLED1 that is shown on the left side part of FIG. 1.

The partition wall PI is disposed between, and divides, the first organic EL element OLED1 and second organic EL element OLED2. In addition, the partition wall PI is disposed between, and divides, the second organic EL element OLED2 and third organic EL element OLED3. Further, the partition wall PI is disposed between, and divides, the third organic EL element OLED3 and first organic EL element OLED1.

The counter-substrate SUB2 is disposed above the first to third organic EL elements OLED1 to OLED3 which are formed on the array substrate 100. The counter-substrate SUB2 is a light-transmissive, insulative substrate such as a glass substrate or a plastic substrate.

In the example illustrated, the array substrate 100 and counter-substrate SUB2 are separated, and a space is present therebetween. Alternatively, a protection film and/or a resin layer, which covers the first to third organic EL elements OLED1 to OLED3, may be disposed between the array substrate 100 and counter-substrate SUB2. The protection film is formed of an insulating material which has light transmissivity and is hardly permeable to moisture, for instance, an inorganic compound such as silicon nitride or silicon oxynitride. The protection film functions as a moisture barrier film which covers the first to third organic EL elements OLED1 to OLED3, and prevents permeation of moisture into the first to third organic EL elements OLED1 to OLED3. The resin layer is formed of a light-transmissive organic compound such as a thermosetting resin or ultraviolet-curing resin. The resin layer functions as a filling layer which is filled between the array substrate 100 and the counter-substrate SUB2, or an adhesive layer which bonds the array substrate 100 and the counter-substrate SUB2. Preferably, the above-described protection film should be interposed between the first to third organic EL elements OLED1 to OLED3 and the resin layer.

In the present embodiment, although the organic layer ORG including a light emitting layer is a continuous film extending over the first to third organic EL elements OLED1 to OLED3, the first to third organic EL elements OLED1 to OLED3 are configured to have different emission light colors. In this example, the emission light color of the first organic EL element OLED1 is red, the emission light color of the second organic EL element OLED2 is green, and the emission light color of the third organic EL element OLED3 is blue.

In this example, the range of a major wavelength between 595 nm and 800 nm is defined as a first wavelength range, and the color in the first wavelength range is set to be red. The range of a major wavelength, which is greater than 490 nm and less than 595 nm, is defined as a second wavelength range, and the color in the second wavelength range is set to be green. The range of a major wavelength between 400 nm to 490 nm is defined as a third wavelength range, and the color in the third wavelength range is set to be blue.

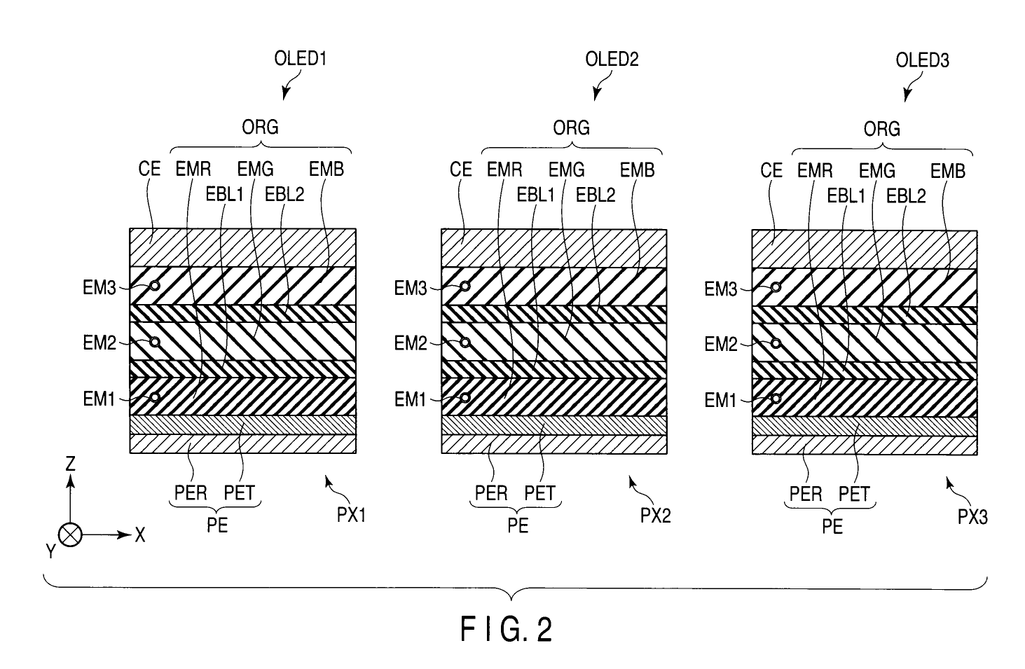

FIG. 2 schematically shows the structure of each of the first to third organic EL elements OLED1 to OLED3. As shown in FIG. 2, each of the first organic EL element OLED1 disposed in the pixel PX1, the second organic EL element OLED2 disposed in the pixel PX2 and the third organic EL element OLED3 disposed in the pixel PX3 includes a pixel electrode PE, a counter-electrode CE that is opposed to the pixel electrode PE, and an organic layer ORG that is interposed between the pixel electrode PE and counter-electrode CE.

The first to third organic EL elements OLED1 to OLED3 are structured as described below.

The pixel electrode PE has a two-layer structure comprising a reflective layer PER and a transmissive layer PET which is disposed between the reflective layer PER and a red light emission layer EMR. The structure of the pixel electrode PE is not limited to this example. The reflective layer PER is formed of a light-reflective electrically conductive material such as silver (Ag) or aluminum (Al). The transmissive layer PET is formed of a light-transmissive electrically conductive material, for instance, an oxide electrically conductive material such as indium tin oxide (ITO) or indium zinc oxide (IZO).

The organic layer ORG is disposed on the pixel electrode PE. The organic layer ORG includes the red light emission layer EMR which is a first light emission layer disposed commonly on the respective pixel electrodes PE; a first exciton block layer EBL1 disposed on the red light emission layer EMR; a green light emission layer EMG which is a second light emission layer disposed on the first exciton block layer EBL1; a second exciton block layer EBL2 disposed on the green light emission layer EMG; and a blue light emission layer EMB which is a third light emission layer disposed on the second exciton block layer EBL2.

The counter-electrode CE is disposed on the organic layer ORG. The counter-electrode CE is composed of a semi-transmissive layer. This semi-transmissive layer is formed of an electrically conductive material such as magnesium (Mg)—silver (Ag).

The red light emission layer EMR is formed of a mixture of a host material and a first dopant material EM1 whose emission light color is red. The first dopant material EM1 is a red light-emitting material which is formed of a luminescent organic compound or composition having a first central light emission wavelength in red wavelengths of the first wavelength range. The red light emission layer EMR is formed, for example, by using tris(8-hydroxyquinolato)aluminum (abbreviation: Alq₃) as the host material, and 4-(dicyanomethylene)-2-tert-butyl-6-(1,1,7,7-tetramethyljulolidin-4-yl-vinyl)-4H-pyran (abbreviation: DCJTB) as the first dopant material EM1. Alternatively, other materials may be used.

The green light emission layer EMG is formed of a mixture of a host material and a second dopant material EM2 whose emission light color is green. The second dopant material EM2 is a green light-emitting material which is formed of a luminescent organic compound or composition having a second central light emission wavelength in green wavelengths of the second wavelength range. The second central light emission wavelength is shorter than the first central light emission wavelength. The green light emission layer EMG is formed, for example, by using 4,4′-bis(carbazole-9-yl) biphenyl (abbreviation: CBP) as the host material, and tris(2-phenylpyridine)iridium (III) (abbreviation: Ir(ppy)3) as the second dopant material EM2. Alternatively, other materials are usable.

The blue light emission layer EMB is formed of a mixture of a host material and a third dopant material EM3 whose emission light color is blue. The third dopant material EM3 is a blue light-emitting material which is formed of a luminescent organic compound or composition having a third central light emission wavelength in blue wavelengths of the third wavelength range. The third central light emission wavelength is shorter than the second central light emission wavelength. The blue light emission layer EMB is formed, for example, by using 4,4′-bis(2,2′-diphenyl-ethen-1-yl)-diphenyl (BPVBI) as the host material, and perylene as the third dopant material EM3. Alternatively, other materials are usable.

For example, at least one of the first dopant material EM1, second dopant material EM2 and third dopant material EM3 may be a phosphorescent material including a metal complex compound.

Each of the first exciton block layer EBL1 and second exciton block layer EBL2 is formed of a nonmetal element such as CBP which is used as the host material.

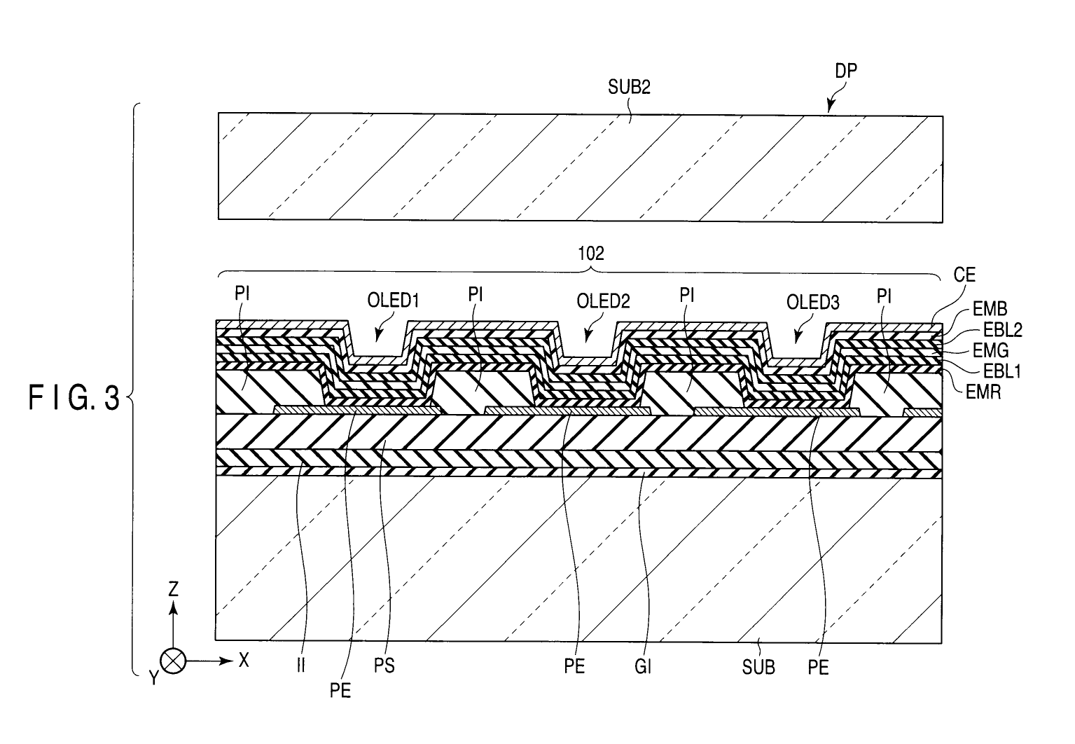

FIG. 3 schematically shows the cross-sectional structure of a display panel DP including first to third organic EL elements OLED1 to OLED3 according to Example 1. FIG. 3 shows the cross-sectional structure which does not include the switching transistor.

As shown in FIG. 3, the gate insulation film GI, interlayer insulation film II and passivation film PS are interposed between the insulative substrate SUB and the pixel electrode PE of each of the first to third organic EL elements OLED1 to OLED3. The respective pixel electrodes PE are disposed on the passivation film PS, and have the same structure.

The red light emission layer EMR is commonly disposed on the pixel electrodes PE of the first to third organic EL elements OLED1 to OLED3. The red light emission layer EMR extends over the first to third organic EL elements OLED1 to OLED3.

Specifically, the red light emission layer EMR is a continuous film spreading over the active area 102, and is disposed common to the first to third organic EL elements OLED1 to OLED3. In addition, the red light emission layer EMR is disposed on each of the partition walls PI which are disposed between the first organic EL element OLED1 and second organic EL element OLED2, between the second organic EL element OLED2 and third organic EL element OLED3, and between the third organic EL element OLED3 and first organic EL element OLED1.

The first exciton block layer EBL1 extends over the first to third organic EL elements OLED1 to OLED3, and is disposed on the red light emission layer EMR. Specifically, the first exciton block layer EBL1 is a continuous film spreading over the active area 102.

The green light emission layer EMG extends over the first to third organic EL elements OLED1 to OLED3, and is disposed on the first exciton block layer EBL1. Specifically, the green light emission layer EMG is a continuous film spreading over the active area 102.

The second exciton block layer EBL2 extends over the first to third organic EL elements OLED1 to OLED3, and is disposed on the green light emission layer EMG. Specifically, the second exciton block layer EBL2 is a continuous film spreading over the active area 102.

The blue light emission layer EMB extends over the first to third organic EL elements OLED1 to OLED3, and is disposed on the second exciton block layer EBL2. Specifically, the blue light emission layer EMB is a continuous film spreading over the active area 102.

The counter-electrode CE extends over the first to third organic EL elements OLED1 to OLED3, and is disposed on the blue light emission layer EMB. Specifically, the counter-electrode CE is a continuous film spreading over the active area 102.

The counter-substrate SUB2 is disposed above the first to third organic EL elements OLED1 to OLED3.

Next, a description is given of the principle for controlling the emission light colors in the first to third organic EL elements OLED1 to OLED3.

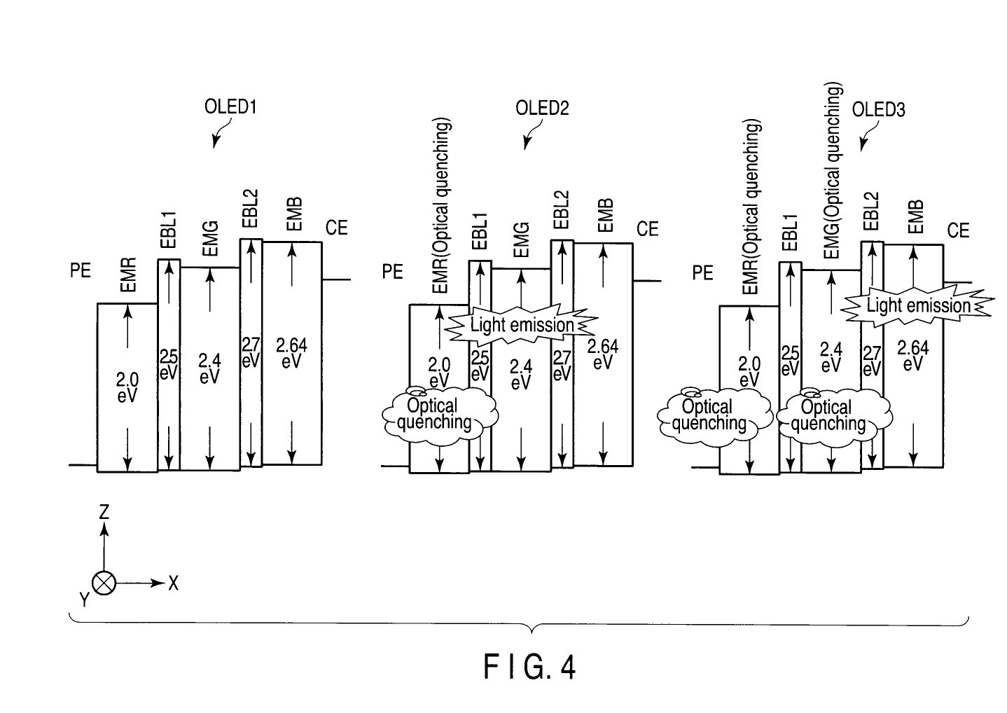

FIG. 4 is a view for explaining the energy levels of the organic layers ORG of the first to third organic EL elements OLED1 to OLED3.

In FIG. 4, the band gap of the red light emission layer EMR corresponds to the band gap of the first dopant material EM1, the band gap of the green light emission layer EMG corresponds to the band gap of the second dopant material EM2, and the band gap of the blue light emission layer EMB corresponds to the band gap of the third dopant material EM3. The band gap of the first dopant material EM1 is smaller than the band gap of each of the second dopant material EM2 and third dopant material EM3. The band gap of the second dopant material EM2 is smaller than the band gap of the third dopant material EM3. The band gap corresponds to an energy difference between a lowest unoccupied molecular orbital (LUMO) and a highest occupied molecular orbital (HOMO).

Examples of the band gaps of the respective layers included in the organic layers ORG of the first to third organic EL elements OLED1 to OLED3 are shown below.

The band gap of the red light emission layer EMR is 2.0 eV, the band gap of the first exciton block layer EBL1 is 2.5 eV, the band gap of the green light emission layer EMG is 2.4 eV, the band gap of the second exciton block layer EBL2 is 2.7 eV, and the band gap of the blue light emission layer EMB is 2.64 eV.

In the first organic EL element OLED1, a material in which electron portability is higher than a hole portability is selected for the respective layers included in the organic layer ORG. Alternatively, a material having a very low hole transportability is selected for only the red light emission layer EMR, this hole transportability being much lower than the hole transportability in the other layers. Thereby, a carrier balance is adjusted so that electrons and holes are combined in the red light emission layer EMR. In the first organic EL element OLED1, since the band gap of the first dopant material EM1 that is included in the red light emission layer EMR is smallest, no energy transition occurs to other layers. Therefore, the first organic EL element OLED1 emits red light, and neither the green light emission layer EMG nor blue light emission layer EMB emits light.

In the second organic EL element OLED2, the first dopant material EM1 of the red light emission layer EMR is in an optical quenching state. The optical quenching state refers to a state in which the dopant material absorbs ultraviolet and thus decomposition, polymerization or a change in molecular structure occurs in the dopant material, and, as a result, light emission does not occur or light emission hardly occurs. In the red light emission layer EMR of the second organic EL element OLED2, the first dopant material EM1 emits no light. Even if the first dopant material EM1 is optically quenched, the band gap in the red light emission layer EMR is 2.0 eV, which is substantially equal to the band gap prior to the optical quenching. It is possible that the band gap in the red light emission layer EMR may become lower than the band gap prior to the optical quenching of the first dopant material EM1.

At this time, in the red light emission layer EMR of the second organic EL element OLED2, the hole injectability or hole transportability of the red light emission layer EMR increases by the ultraviolet irradiation for the optical quenching of the first dopant material EM1, and the hole mobility becomes higher than in the state prior to the ultraviolet radiation. Hence, in the second organic EL element OLED2, the balance between electrons and holes varies, and the light emission position shifts to the green light emission layer EMG. Therefore, the second organic EL element OLED2 emits green light, and the blue light emission layer EMB emits no light.

The band gap of the first exciton block layer EBL1 is higher than the band gap of the second dopant material EM2 of the green light emission layer EMG. Thus, the first exciton block layer EBL1 prevents the energy of excitons, which are generated in the green light emission layer EMG, from transitioning to the red light emission layer EMR.

In the meantime, it should suffice if the first exciton block layer EBL1 has such a thickness as to effectively prevent the energy transition of excitons from the green light emission layer EMG to the red light emission layer EMR. Thus, compared to the thickness of a general light emission layer, for example, 30 nm, the thickness of the first exciton block layer EBL1 is about 5 nm and is very small. Therefore, since the influence on the carrier balance is very small, the shift of the light emission position to the green light emission layer EMG is not hindered in the second organic EL element OLED2.

In the third organic EL element OLED3, the first dopant material EM1 of the red light emission layer EMR and the second dopant material EM2 of the green light emission layer EMG are in the optical quenching state. In the red light emission layer EMR of the third organic EL element OLED3, the first dopant material EM1 emits no light. In addition, in the green light emission layer EMG of the third organic EL element OLED3, the second dopant material EM2 emits no light. The band gap in the red light emission layer EMR is 2.0 eV, which is substantially equal to the band gap prior to the optical quenching of the first dopant material EM1. In addition, the band gap in the green light emission layer EMG is 2.4 eV, which is substantially equal to the band gap prior to the optical quenching of the second dopant material EM2.

At this time, in the red light emission layer EMR of the third organic EL element OLED3, like the second organic EL element OLED2, the hole injectability or hole transportability increases. Similarly, in the green light emission layer EMG of the third organic EL element OLED3, the hole injectability or hole transportability of the green light emission layer EMG increases by the ultraviolet irradiation for the optical quenching of the second dopant material EM2, and the hole mobility becomes higher than in the state prior to the ultraviolet radiation.

Hence, in the third organic EL element OLED3, the balance between electrons and holes further varies, and the light emission position shifts to the blue light emission layer EMB. Therefore, the third organic EL element OLED3 emits blue light.

The band gap of the second exciton block layer EBL2 is higher than the band gap of the third dopant material EM3 of the blue light emission layer EMB. Thus, the second exciton block layer EBL2 prevents the energy of excitons, which are generated in the blue light emission layer EMB, from transitioning to the green light emission layer EMG.

In the meantime, like the first exciton block layer EBL1, it should suffice if the second exciton block layer EBL2 has such a thickness as to effectively prevent the energy transition of excitons from the blue light emission layer EMB to the green light emission layer EMG. Thus, the thickness of the second exciton block layer EBL2 is about 5 nm and is very small. Therefore, since the influence on the carrier balance is very small, the shift of the light emission position to the blue light emission layer EMB is not hindered in the third organic EL element OLED3.

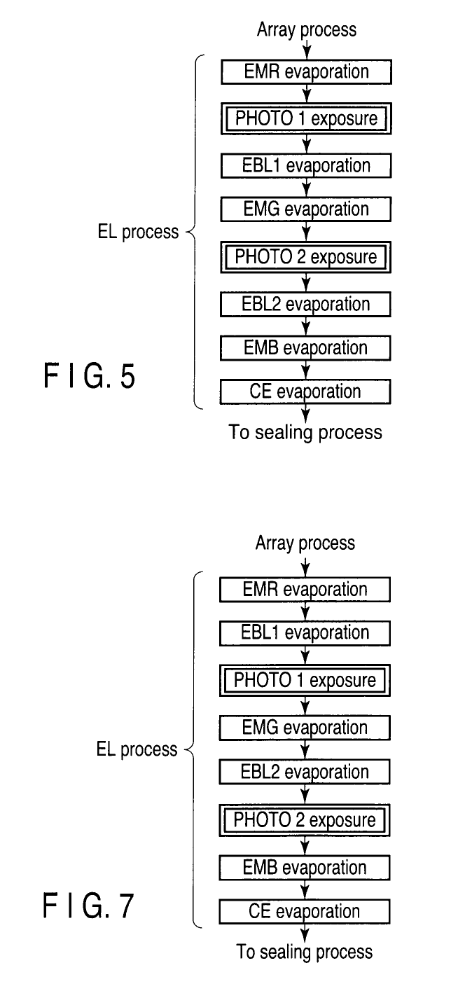

Next, referring to a flow chart of FIG. 5, a description is given of an example of a manufacturing method of the first to third organic EL elements OLED1 to OLED3 in Example 1.

To start with, in an array process, pixel electrodes PE are formed on a passivation film PS in the pixels PX1 to PX3 in which the first to third organic EL elements OLED1 to OLED3 are to be formed.

Then, in an EL process, a red light emission layer EMR including a first dopant material EM1 is formed on each pixel electrode PE by a vacuum evaporation method by using a rough mask in which an opening corresponding to the active area 102 is formed. This red light emission layer EMR is disposed common to the respective pixel electrodes PE. In FIG. 5, this step is indicated by “EMR EVAPORATION”.

Then, regions, which correspond to the pixel PX2 in which the second organic EL element OLED2 is formed and the pixel PX3 in which the third organic EL element OLED3 is formed, are irradiated with ultraviolet light in a range of wavelengths of about 200 to 400 nm with an intensity in a range of 0.001 to 1.0 mW·mm⁻²·nm⁻¹. In this example, the intensity of ultraviolet light is set at about 0.1 mW·mm⁻²·nm⁻¹. Thereby, the red light emission layer EMR, which is positioned above the pixel electrodes PE disposed in the pixel PX2 and pixel PX3, is exposed. In FIG. 5, this step is indicated by “PHOTO1 EXPOSURE”.

Subsequently, a first exciton block layer EBL1 is formed on the red light emission layer EMR by a vacuum evaporation method by using a rough mask in which an opening corresponding to the active area 102 is formed. In FIG. 5, this step is indicated by “EBL1 EVAPORATION”.

Then, a green light emission layer EMG including a second dopant material EM2 is formed on the first exciton block layer EBL1 by a vacuum evaporation method by using a rough mask in which an opening corresponding to the active area 102 is formed. In FIG. 5, this step is indicated by “EMG EVAPORATION”.

Thereafter, the region, which corresponds to the pixel PX3, is irradiated with ultraviolet light in a range of wavelengths of about 200 to 400 nm with an intensity in a range of 0.001 to 1.0 mW·mm⁻²·nm⁻¹. In this example, the intensity of ultraviolet light is set at about 0.1 mW·mm⁻²·nm⁻¹. Thereby, the green light emission layer EMG, which is positioned above the pixel electrodes PE disposed in the pixel PX3, is exposed. In FIG. 5, this step is indicated by “PHOTO2 EXPOSURE”. In the meantime, ultraviolet lights with different wavelengths may be radiated in the “PHOTO1 EXPOSURE” and “PHOTO2 EXPOSURE”.

Subsequently, a second exciton block layer EBL2 is formed on the green light emission layer EMG by a vacuum evaporation method by using a rough mask in which an opening corresponding to the active area 102 is formed. In FIG. 5, this step is indicated by “EBL2 EVAPORATION”.

Then, a blue light emission layer EMB including a third dopant material EM3 is formed on the second exciton block layer EBL2 by a vacuum evaporation method by using a rough mask in which an opening corresponding to the active area 102 is formed. In FIG. 5, this step is indicated by “EMB EVAPORATION”.

Subsequently, a counter-electrode CE is formed on the blue light emission layer EMB. In FIG. 5, this step is indicated by “CE EVAPORATION”.

Thereafter, a sealing process by the counter-substrate SUB2, etc. is performed.

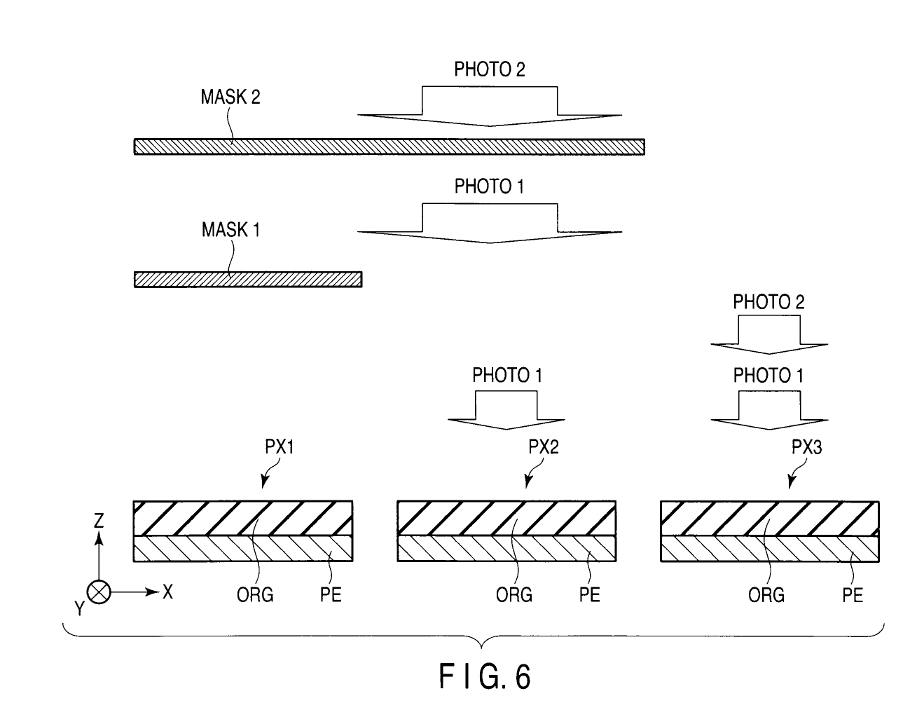

As shown in FIG. 6, in the exposure step indicated by “PHOTO1”, ultraviolet light is radiated by using a photomask MASK1 which shields the pixel PX1 from light and has an opening facing the pixels PX2 and PX3. Thereby, in the red light emission layer EMR that is formed in the preceding step, the first dopant material EM1 of the red light emission layer EMR that is formed in the pixels PX2 and PX3 absorbs ultraviolet light and transitions into an optical quenching state.

In the subsequent exposure step indicated by “PHOTO2”, ultraviolet light is radiated by using a photomask MASK2 which shields the pixel PX1 and pixel PX2 from light and has an opening facing the pixel PX3. Thereby, in the green light emission layer EMG that is formed in the preceding step, the second dopant material EM2 of the green light emission layer EMG that is formed in the pixel PX3 absorbs ultraviolet light and transitions into an optical quenching state.

FIG. 7 shows a flow chart illustrating another manufacturing method of the first to third organic EL elements OLED1 to OLED3.

Specifically, after the array process, the EL process is performed which comprises “EMR EVAPORATION” for forming the red light emission layer EMR, “EBL1 EVAPORATION” for forming the first exciton block layer EBL1, “PHOTO1 EXPOSURE” for exposing the red light emission layer EMR of the pixel PX2 and pixel PX3, “EMG EVAPORATION” for forming the green light emission layer EMG, “EBL2 EVAPORATION” for forming the second exciton block layer EBL2, “PHOTO2 EXPOSURE” for exposing the green light emission layer EMG of the pixel PX3, “EMB EVAPORATION” for forming the blue light emission layer EMB, and “CE EVAPORATION” for forming the counter-electrode CE. Thereafter, the sealing process is performed.

Next, the optical quenching of the dopant materials is explained.

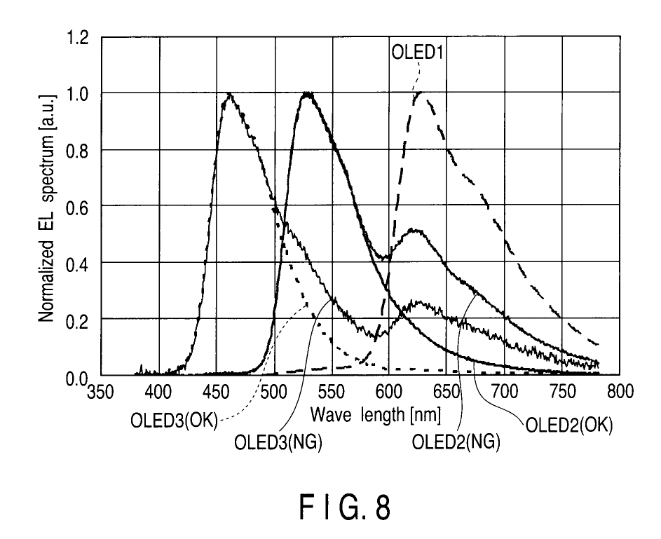

FIG. 8 shows examples of emission light spectra of the first to third organic EL elements OLED1 to OLED3. In FIG. 8, the emission light spectra of the first to third organic EL elements OLED1 to OLED3 are normalized by the respective maximum peak intensities.

In the first organic EL element OLED1, the first dopant material EM1 of the red light emission layer EMR emits light. As indicated by OLED1 in FIG. 8, the emission light spectrum of the first organic EL element OLED1 has a maximum peak intensity in the vicinity of the wavelength of 625 nm.

In the second organic EL element OLED2, the second dopant material EM2 of the green light emission layer EMG emits light. Accordingly, the emission light spectrum of the second organic EL element OLED2 has a maximum peak intensity in the vicinity of the wavelength of 525 nm.

OLED2(OK) in FIG. 8 indicates the emission light spectrum in the state in which the first dopant material EM1 of the red light emission layer EMR in the second organic EL element OLED2 is optically quenched. In the emission light spectrum of the second organic EL element OLED2, the spectrum intensity is 20% or less in the vicinity of the wavelength of 625 nm at which the first organic EL element OLED1 takes the maximum peak intensity. In the state in which the first dopant material EM1 is optically quenched, no spectrum peak appears in the vicinity of the wavelength of 625 nm in the emission light spectrum of the second organic EL element OLED2.

On the other hand, OLED2(NG) in FIG. 8 indicates the emission light spectrum in the case where the first dopant material EM1 of the red light emission layer EMR in the second organic EL element OLED2 is not in the optical quenching state or the optical quenching process is deficient. In the emission light spectrum of the second organic EL element OLED2, the spectrum intensity exceeds 20% and is about 50% in the vicinity of the wavelength of 625 nm. In addition, in the emission light spectrum of the second organic EL element OLED2, a spectrum peak appears in the vicinity of the wavelength of 625 nm.

In the present embodiment, the state in which the first dopant material EM1 is optically quenched is defined as a state in which the spectrum intensity in the vicinity of the major wavelength of red is 20% or less, as indicated by OLED2(OK), or a state in which no spectrum peak appears in the vicinity of the major wavelength of red.

In the third organic EL element OLED3, the third dopant material EM3 of the blue light emission layer EMB emits light. Accordingly, the emission light spectrum of the third organic EL element OLED3 has a maximum peak intensity in the vicinity of the wavelength of 460 nm.

OLED3(OK) in FIG. 8 indicates the emission light spectrum in the state in which the first dopant material EM1 of the red light emission layer EMR and the second dopant material EM2 of the green light emission layer EMG in the third organic EL element OLED3 are optically quenched. In the emission light spectrum of the third organic EL element OLED3, the spectrum intensity is 20% or less in the vicinity of the wavelength of 625 nm at which the first organic EL element OLED1 takes the maximum peak intensity and in the vicinity of the wavelength of 525 nm at which the second organic EL element OLED2 takes the maximum peak intensity. In the state in which the first dopant material EM1 is optically quenched, no spectrum peak appears in the vicinity of the wavelength of 625 nm in the emission light spectrum of the third organic EL element OLED3. Similarly, in the state in which the second dopant material EM2 is optically quenched, no spectrum peak appears in the vicinity of the wavelength of 525 nm in the emission light spectrum of the third organic EL element OLED3.

On the other hand, OLED3(NG) in FIG. 8 indicates the emission light spectrum in the case where the first dopant material EM1 of the red light emission layer EMR and the second dopant material EM2 of the green light emission layer EMG in the third organic EL element OLED3 are not in the optical quenching state or the optical quenching process is deficient. In the emission light spectrum of the third organic EL element OLED3, the spectrum intensity exceeds 20% and is about 30% in the vicinity of the wavelength of 625 nm and the spectrum intensity exceeds 20% and is about 40% in the vicinity of the wavelength of 525 nm. In addition, in the emission light spectrum of the third organic EL element OLED3, a spectrum peak appears in the vicinity of the wavelength of 625 nm.

In the present embodiment, the state in which the first dopant material EM1 and second dopant material EM2 are optically quenched is defined as a state in which the spectrum intensity in the vicinity of the major wavelengths of red and green is 20% or less, as indicated by OLED3(OK), or a state in which no spectrum peak appears in the vicinity of the major wavelengths of red and green.

As has been described above, each of the red light emission layer EMR, green light emission layer EMG and blue light emission layer EMB is a continuous film extending over the first to third organic EL elements OLED1 to OLED3. Similarly, each of the first exciton block layer EBL1, second exciton block layer EBL2 and counter-electrode CE is a continuous film extending over the first to third organic EL elements OLED1 to OLED3. Thus, when these films are formed by the evaporation method, a fine mask in which a fine opening is formed is needless, and the manufacturing cost of the mask can be reduced. In addition, when these films are formed, the amount of material deposited on the mask decreases, and the efficiency of use of the material of the films is enhanced. Moreover, since there is no need to selectively apply the light-emitting materials, a defect of color mixture can be prevented.

Besides, the second organic EL element OLED2 emits green light since the first dopant material EM1 of the red light emission layer EMR is in the optical quenching state. The third organic EL element OLED3 emits blue light since the first dopant material EM1 of the red light emission layer EMR and the second dopant material EM2 of the green light emission layer EMG are in the optical quenching state. Accordingly, full-color display with high fineness can be realized.

Furthermore, in the first to third EL elements OLED1 to OLED3, the first exciton block layer EBL1 is disposed between the red light emission layer EMR and green light emission layer EMG. The first exciton block layer EBL1 has a larger band gap than the green light emission layer EMG. Thus, in the second organic EL element OLED2, the first exciton block layer EBL1 prevents part of the energy of excitons, which are generated in the green light emission layer EMG, from transitioning to the red light emission layer EMR which has a smaller band gap than the green light emission layer EMG. Therefore, it is possible to suppress a decrease in light emission efficiency of green in the second organic EL element OLED2.

Similarly, in the first to third EL elements OLED1 to OLED3, the second exciton block layer EBL2 is disposed between the green light emission layer EMG and blue light emission layer EMB. The second exciton block layer EBL2 has a larger band gap than the blue light emission layer EMB. Thus, in the third organic EL element OLED3, the second exciton block layer EBL2 prevents part of the energy of excitons, which are generated in the blue light emission layer EMB, from transitioning to the green light emission layer EMG. Therefore, it is possible to suppress a decrease in light emission efficiency of blue in the third organic EL element OLED3.

A description is given of examples of variations of elements, which can be adopted in the first to third organic EL elements OLED1 to OLED3 in the present embodiment.

For example, the pixel electrode PE, which has been described above, has the two-layer structure comprising the reflective layer PER and the transmissive layer PET which is stacked on the reflective layer PER. Alternatively, the pixel electrode PE may have a single transmissive layer structure, a single reflective layer structure, or a stacked structure of three or more layers. In the case where each of the first to third organic EL elements OLED1 to OLED3 is of the top emission type in which light is emitted from the counter-substrate SUB2 side, the pixel electrode PE includes at least the reflective layer PER. In the case where each of the first to third organic EL elements OLED1 to OLED3 is of the bottom emission type in which light is emitted from the insulative substrate SUB side, the pixel electrode PE does not include the reflective layer PER.

The organic layer ORG may include a hole injection layer and/or a hole transport layer between the pixel electrode PE and the red light emission layer EMR. In addition, the organic layer ORG may include an electron injection layer and/or an electron transport layer between the counter-electrode CE and the blue light emission layer EMB. Although the term “organic layer” is used, a part of the light emission layer, hole injection layer, hole transport layer, electron injection layer and electron transport layer may be formed of an inorganic material.

The above description has been directed to the case in which the counter-electrode CE is formed of the semi-transmissive layer. However, the counter-electrode CE may have a two-layer structure in which a semi-transmissive layer and a transmissive layer are stacked. In addition, the counter-electrode CE may have a single transmissive layer structure or a single semi-transmissive layer structure. The transmissive layer can be formed of a light-transmissive, electrically conductive material such as ITO or IZO.

The first to third organic EL elements OLED1 to OLED3 may adopt a micro-cavity structure which comprises a pixel electrode PE having a reflective layer, and a counter-electrode CE including a semi-transmissive layer.

In the case where the micro-cavity structure is adopted, a light-transmissive insulation film, for instance, silicon oxynitride (SiON), may be disposed on the counter-electrode CE. Such an insulation film is usable as a protection film for protecting the first to third organic EL elements OLED1 to OLED3, and is also usable as an optical matching layer for adjusting the optical path length for optimizing optical interference. Moreover, a light-transmissive insulation film, for instance, silicon nitride (SiN), may be disposed between the reflective layer and the semi-transmissive layer. Such an insulation film is usable as an adjusting layer for adjusting an optical interference condition. The optical path length of such an adjusting layer is set at a least common multiple of ¼ of the wavelength of emission light of each of the first to third organic EL elements OLED1 to OLED3. The thickness of the adjusting layer is, e.g. 410 nm. Such an adjusting layer may be disposed only in the first organic EL element OLED1 and the second organic EL element OLED2. The thickness of the adjusting layer in this case is, e.g. 390 nm.

In the above-described embodiment, the description has been given of the case in which the hole injectability or hole transportability in the red light emission layer EMR and green light emission layer EMG is increased by the ultraviolet irradiation for causing optical quenching in the red light emission layer EMR and the green light emission layer EMG. Alternatively, the same advantageous effect can be obtained in the case in which the electron injectability or electron transportability in the red light emission layer EMR and green light emission layer EMG is decreased by the ultraviolet irradiation.

The manufacturing method is not limited to the examples shown in FIG. 5 and FIG. 7. For example, the exposure step “PHOTO1” for exposing the red light emission layer EMR may be performed at a time after the formation of the red light emission layer EMR and before the formation of the counter-electrode CE. In addition, the exposure step “PHOTO2 EXPOSURE” for exposing the green light emission layer EMG may be performed at a time after the formation of the green light emission layer EMG and before the formation of the counter-electrode CE.

Next, other examples of the present embodiment are described.

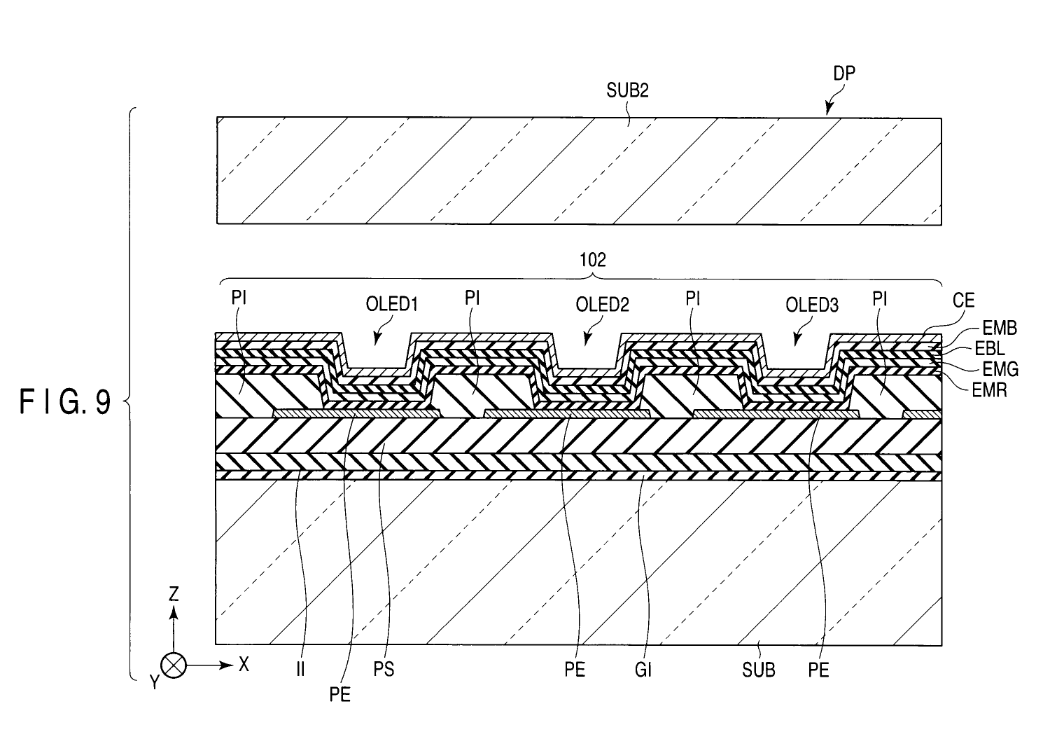

FIG. 9 schematically shows the cross-sectional structure of a display panel DP including first to third organic EL elements OLED1 to OLED3 in Example 2. The cross-sectional structure shown in FIG. 9 does not include switching transistors. Example 2 shown in FIG. 9 differs from Example 1 shown in FIG. 3 in that an electron blocking layer between the red light emission layer EMR and green light emission layer EMG is omitted.

A gate insulation film GI, an interlayer insulation film II and a passivation film PS are interposed between the insulative substrate SUB and the pixel electrode PE of each of the first to third organic EL elements OLED1 to OLED3. A red light emission layer EMR extends over the first to third organic EL elements OLED1 to OLED3, and is commonly disposed on the pixel electrodes PE of the first to third organic EL elements OLED1 to OLED3. The first dopant material is in the quenching state in the red light emission layer EMR of the second organic EL element OLED2 and third organic EL element OLED3.

A green light emission layer EMG extends over the first to third organic EL elements OLED1 to OLED3, and is disposed on the red light emission layer EMR. The second dopant material EM2 is in the optical quenching state in the green light emission layer EMG of the third organic EL element OLED3.

An exciton block layer EBL extends over the first to third organic EL elements OLED1 to OLED3, and is disposed on the green light emission layer EMG. The exciton block layer EBL has a larger band gap than a blue emission light layer EMB.

The blue light emission layer EMB extends over the first to third organic EL elements OLED1 to OLED3, and is disposed on the exciton block layer EBL. A counter-electrode CE extends over the first to third organic EL elements OLED1 to OLED3, and is disposed on the blue light emission layer EMB.

The counter-substrate SUB2 is disposed above the first to third organic EL elements OLED1 to OLED3.

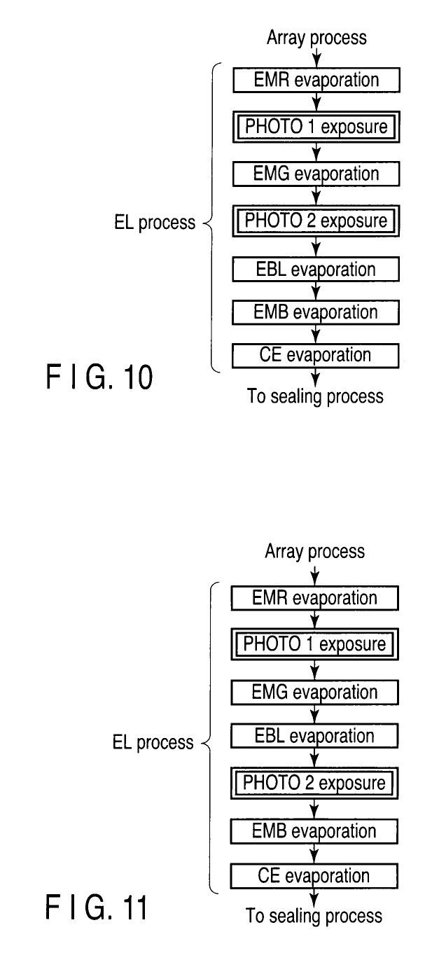

Next, referring to a flow chart of FIG. 10, a description is given of an example of the manufacturing method of the first to third organic EL elements OLED1 to OLED3 in Example 2.

Specifically, after the array process, the EL process is performed which comprises “EMR EVAPORATION” for forming the red light emission layer EMR, “PHOTO1 EXPOSURE” for exposing the red light emission layer EMR of the pixel PX2 and pixel PX3, “EMG EVAPORATION” for forming the green light emission layer EMG, “PHOTO2 EXPOSURE” for exposing the green light emission layer EMG of the pixel PX3, “EBL EVAPORATION” for forming the exciton block layer EBL, “EMB EVAPORATION” for forming the blue light emission layer EMB, and “CE EVAPORATION” for forming the counter-electrode CE. Thereafter, the sealing process is performed.

FIG. 11 shows a flow chart illustrating another manufacturing method of the first to third organic EL elements OLED1 to OLED3 in Example 2.

Specifically, after the array process, the EL process is performed which comprises “EMR EVAPORATION” for forming the red light emission layer EMR, “PHOTO1 EXPOSURE” for exposing the red light emission layer EMR of the pixel PX2 and pixel PX3, “EMG EVAPORATION” for forming the green light emission layer EMG, “EBL EVAPORATION” for forming the exciton block layer EBL, “PHOTO2 EXPOSURE” for exposing the green light emission layer EMG of the pixel PX3, “EMB EVAPORATION” for forming the blue light emission layer EMB, and “CE EVAPORATION” for forming the counter-electrode CE. Thereafter, the sealing process is performed.

In Example 2, too, the same advantageous advantages as in Example 1 can be obtained.

In general, a transition of energy of excitons, which are generated in a light emission layer, to another light emission layer, that is, Förster transition, can occur within a distance of 10 nm or less. In the case where carrier coupling in the green light emission layer EMG including the second dopant material EM2 as the second light emission layer occurs at a position 15 nm away from the interface with the red light emission layer EMR including the first dopant material EM1 as the first light emission layer, the possibility is low that the energy of excitons, which are generated in the green light emission layer EMG, transitions to the red light emission layer EMR. Therefore, there is no need to form an exciton block layer between the red light emission layer EMR and the green light emission layer EMG.

Thereby, compared to Example 1, since the number of times of film formation can be reduced, the productivity is improved. Moreover, the amount of material for use in forming the exciton block layer can be reduced, and the cost of material can be reduced.

All variations of elements, which have been described above in Example 1, are applicable to Example 2.

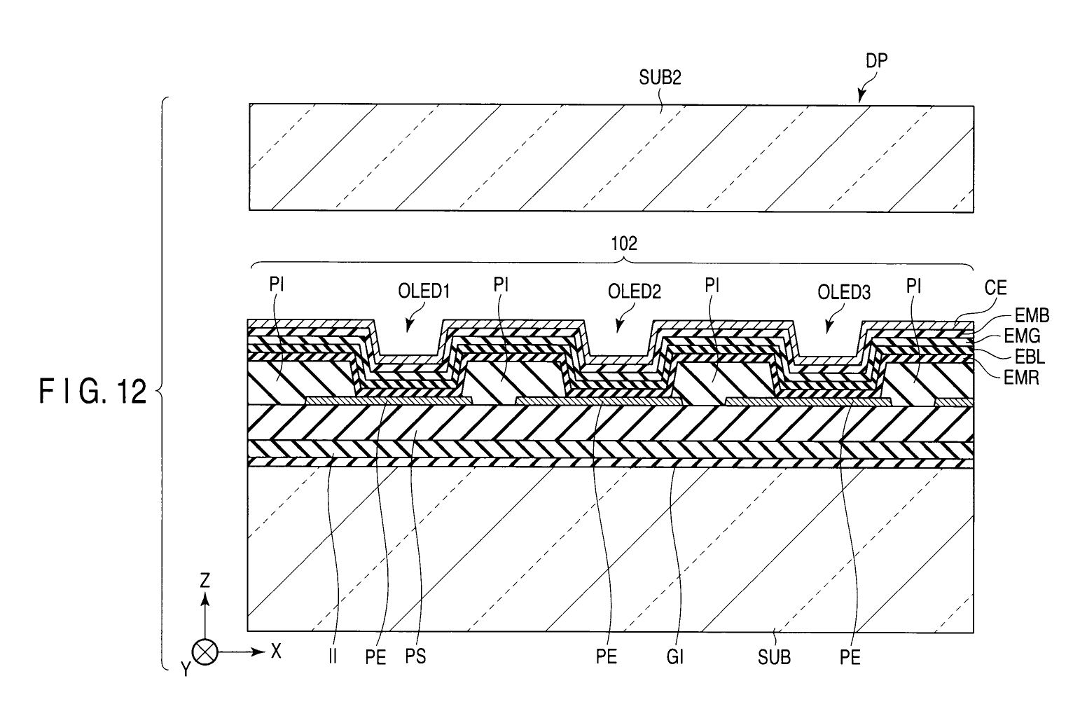

FIG. 12 schematically shows the cross-sectional structure of a display panel DP including first to third organic EL elements OLED1 to OLED3 in Example 3. The cross-sectional structure shown in FIG. 12 does not include switching transistors. Example 3 shown in FIG. 12 differs from Example 1 shown in FIG. 3 in that an electron blocking layer between the green light emission layer EMG and blue light emission layer EMB is omitted.

A gate insulation film GI, an interlayer insulation film II and a passivation film PS are interposed between the insulative substrate SUB and the pixel electrode PE of each of the first to third organic EL elements OLED1 to OLED3. A red light emission layer EMR extends over the first to third organic EL elements OLED1 to OLED3, and is commonly disposed on the pixel electrodes PE of the first to third organic EL elements OLED1 to OLED3. The first dopant material EM1 is in the quenching state in the red light emission layer EMR of the second organic EL element OLED2 and third organic EL element OLED3.

An exciton block layer EBL extends over the first to third organic EL elements OLED1 to OLED3, and is disposed on the red light emission layer EMR. The exciton block layer EBL has a larger band gap than a green emission light layer EMG.

The green light emission layer EMG extends over the first to third organic EL elements OLED1 to OLED3, and is disposed on the exciton block layer EBL. The second dopant material EM2 is in the optical quenching state in the green light emission layer EMG of the third organic EL element OLED3.

A blue light emission layer EMB extends over the first to third organic EL elements OLED1 to OLED3, and is disposed on the green light emission layer EMG. A counter-electrode CE extends over the first to third organic EL elements OLED1 to OLED3, and is disposed on the blue light emission layer EMB.

The counter-substrate SUB2 is disposed above the first to third organic EL elements OLED1 to OLED3.

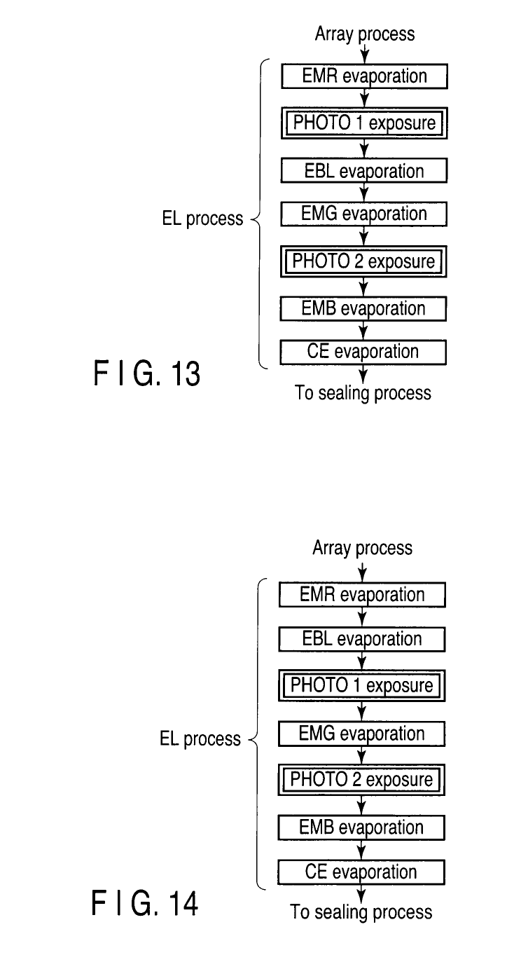

Next, referring to a flow chart of FIG. 13, a description is given of an example of the manufacturing method of the first to third organic EL elements OLED1 to OLED3 in Example 3.

Specifically, after the array process, the EL process is performed which comprises “EMR EVAPORATION” for forming the red light emission layer EMR, “PHOTO1 EXPOSURE” for exposing the red light emission layer EMR of the pixel PX2 and pixel PX3, “EBL EVAPORATION” for forming the exciton block layer EBL, “EMG EVAPORATION” for forming the green light emission layer EMG, “PHOTO2 EXPOSURE” for exposing the green light emission layer EMG of the pixel PX3, “EMB EVAPORATION” for forming the blue light emission layer EMB, and “CE EVAPORATION” for forming the counter-electrode CE. Thereafter, the sealing process is performed.

FIG. 14 shows a flow chart illustrating another manufacturing method of the first to third organic EL elements OLED1 to OLED3 in Example 3.

Specifically, after the array process, the EL process is performed which comprises “EMR EVAPORATION” for forming the red light emission layer EMR, “EBL EVAPORATION” for forming the exciton block layer EBL, “PHOTO1 EXPOSURE” for exposing the red light emission layer EMR of the pixel PX2 and pixel PX3, “EMG EVAPORATION” for forming the green light emission layer EMG, “PHOTO2 EXPOSURE” for exposing the green light emission layer EMG of the pixel PX3, “EMB EVAPORATION” for forming the blue light emission layer EMB, and “CE EVAPORATION” for forming the counter-electrode CE. Thereafter, the sealing process is performed.

In Example 3, too, the same advantageous advantages as in Example 1 can be obtained.

Specifically, in the case where carrier coupling in the blue light emission layer EMB including the third dopant material EM3 as the third light emission layer occurs at a position 15 nm away from the interface with the green light emission layer EMG including the second dopant material EM2 as the second light emission layer, the possibility is low that the energy of excitons, which are generated in the blue light emission layer EMB, transitions to the green light emission layer EMG. Therefore, there is no need to form an exciton block layer between the green light emission layer EMG and blue light emission layer EMB.

Thereby, compared to Example 1, since the number of times of film formation can be reduced, the productivity is improved. Moreover, the amount of material for use in forming the exciton block layer can be reduced, and the cost of material can be reduced.

All variations of elements, which have been described above in Example 1, are applicable to Example 3.

In the above-described Examples, the exposure step “PHOTO1” for exposing the red light emission layer EMR of the pixel PX2 and pixel PX3 is performed at a time between “EMR EVAPORATION” for forming the red light emission layer EMR and “CE EVAPORATION” for forming the counter-electrode CE, and the exposure step “PHOTO2 EXPOSURE” for exposing the green light emission layer EMG of the pixel PX3 is performed at a time between “EMG EVAPORATION” for forming the green light emission layer EMG and “CE EVAPORATION” for forming the counter-electrode CE. However, the method of exposing the red light emission layer EMR and green light emission layer EMG is not limited to these examples.

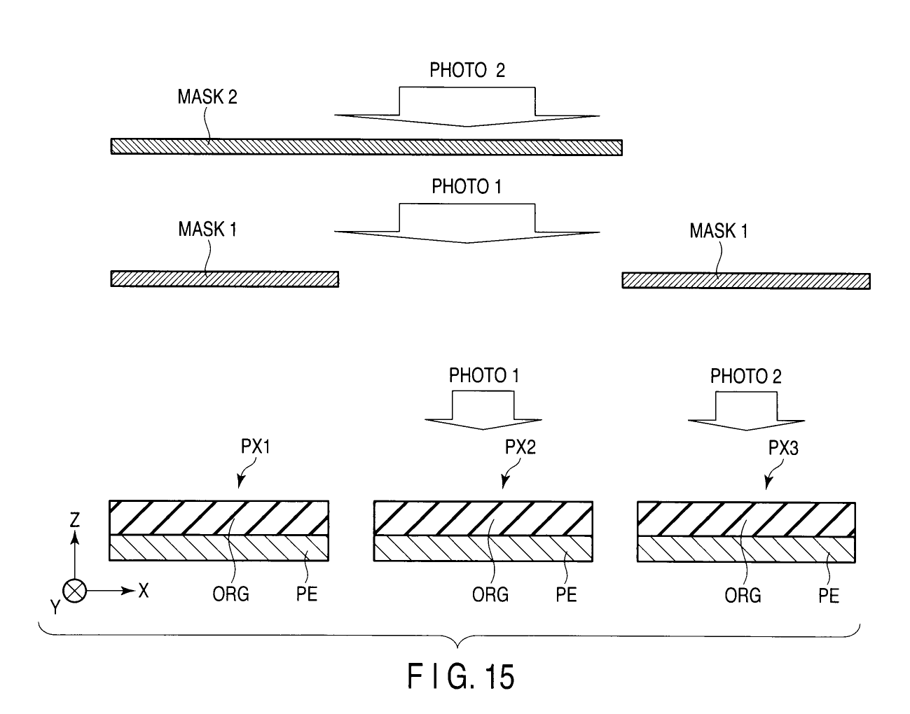

FIG. 15 is a view for explaining another method of “PHOTO1 EXPOSURE” and “PHOTO2 EXPOSURE”.

As shown in FIG. 15, in the exposure step indicated by “PHOTO1”, ultraviolet light is radiated by using a photomask MASK1 which shields the pixel PX1 and pixel PX3 from light and has an opening facing the pixel PX2. Specifically, of the already formed red light emission layer EMR (not shown) that is a part of the organic layer ORG, that part of the red light emission layer EMR, which is positioned above the pixel electrode PE of the pixel PX2, is exposed. Thereby, the first dopant material EM1 of the red light emission layer EMR that is positioned above the pixel electrode PE of the pixel PX2 absorbs ultraviolet light and transitions into an optical quenching state.

In the subsequent exposure step indicated by “PHOTO2”, ultraviolet light is radiated by using a photomask MASK2 which shields the pixel PX1 and pixel PX2 from light and has an opening facing the pixel PX3. Specifically, of the already formed red light emission layer EMR and green light emission layer EMG (neither shown) which are parts of the organic layer ORG, those parts of the red light emission layer EMR and green light emission layer EMG, which are positioned above the pixel electrode PE of the pixel PX3, are exposed. Thereby, the first dopant material EM1 of the red light emission layer EMR and the second dopant material EM2 of the green light emission layer EMG, which are formed above the pixel electrode PE of the pixel PX3, absorb ultraviolet light and transition into an optical quenching state.

In the PHOTO1 exposure that has been described above, the wavelength and intensity of ultraviolet light, which is radiated on the red light emission layer EMR, are properly adjusted within such a necessary range as to cause at least the first dopant material EM1 to absorb the ultraviolet light and to transition to the optical quenching state.

In addition, in the PHOTO2 exposure that has been described above, the wavelength and intensity of ultraviolet light, which is radiated on the red light emission layer EMR and green light emission layer EMG, are properly adjusted within such a necessary range as to cause at least the first dopant material EM1 and second dopant material EM2 to absorb the ultraviolet light and to transition to the optical quenching state.

The PHOTO1 exposure that has been described above may be performed at any time after the EMR evaporation for forming the red light emission layer EMR and before the CE evaporation for forming the counter-electrode CE. However, if there is a concern that the second dopant material EM2 included in the green light emission layer EMG and the third dopant material EM3 included in the blue light emission layer EMB may absorb ultraviolet light which is radiated toward the pixel PX2 and may transition into the optical quenching state, it is desirable to perform the PHOTO1 exposure before the EMG evaporation for forming the green light emission layer EMG and the EMB evaporation for forming the blue light emission layer EMB.

In addition, the PHOTO2 exposure that has been described above may be performed at any time after the EMG evaporation for forming the green light emission layer EMG and before the CE evaporation for forming the counter-electrode CE. However, if there is a concern that the third dopant material EM3 included in the blue light emission layer EMB may absorb ultraviolet light which is radiated toward the pixel PX3 and may transition into the optical quenching state, it is desirable to perform the PHOTO2 exposure before the EMB evaporation for forming the blue light emission layer EMB.

With the application of the exposure steps shown in FIG. 15, in the case where the pixel PX2 and pixel PX3 have the same shape and area, the photomask MASK1 and photomask MASK2, which are used in exposing the pixel PX2 and pixel PX3, may be the same. Specifically, simply by preparing one kind of photomask and varying the alignment position between the pixel and the photomask, the PHOTO1 exposure and PHOTO2 exposure can be performed, and the manufacturing cost can be reduced.

The present invention is not limited directly to the above-described embodiments. In practice, the structural elements can be modified and embodied without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

In the above-described examples, the organic EL display device includes three kinds of organic EL elements with different emission light colors, namely, the first to third organic EL elements OLED1 to OLED3. Alternatively, the organic EL display device may include, as organic EL elements, only two kinds of organic EL elements with different emission light colors, or four or more kinds of organic EL elements with different emission light colors.

In the present embodiment, the description has been given of the case in which when the dopant material is in an optical quenching state, no light is emitted at all from the dopant material. However, if the same advantageous effect can be obtained, the invention is applicable to the case in which when the dopant material is in an optical quenching state, light is hardly emitted from the dopant material.

The present embodiment has been described with respect to the organic EL display device as the organic EL device, but the invention is applicable to organic EL illumination equipment, an organic EL printer head, etc.

What is claimed is:

1. An organic EL device comprising:
an insulative film;
first to third pixel electrodes disposed on the insulative film;
a first light emission layer which includes a first dopant material and is commonly disposed above the first to third organic pixel electrodes;
a second light emission layer which includes a second dopant material and is disposed above the first light emission layer;
a third light emission layer which includes a third dopant material and is disposed above the second light emission layer;
a counter-electrode disposed above the third light emission layer; and
an exciton block layer disposed at least between the first light emission layer and the second light emission layer or between the second light emission layer and the third light emission layer,
wherein an emission light color between the first pixel electrode and the counter-electrode, an emission light color between the second pixel electrode and the counter-electrode and an emission light color between the third pixel electrode and the counter-electrode are different from each other.

2. The organic EL device according to claim 1, wherein the first dopant material included in the first light emission layer between the second pixel electrode and the counter-electrode is optically quenched, and
the first dopant material included in the first light emission layer and the second dopant material included in the second light emission layer between the third pixel electrode and the counter-electrode are optically quenched.

3. The organic EL device according to claim 1, wherein at least one of the first dopant material, the second dopant material and the third dopant material is a phosphorescent material.

4. The organic EL device according to claim 1, wherein the first dopant material has a first central light emission wavelength, the second dopant material has a second central light emission wavelength which is shorter than the first central light emission wavelength, and the third dopant material has a third central light emission wavelength which is shorter than the second central light emission wavelength.

5. The organic EL device according to claim 1, wherein at least one of the first to third light emission layers includes a metal complex compound.

6. The organic EL device according to claim 1, wherein the exciton block layer disposed between the first light emission layer and the second light emission layer has a larger band gap than a band gap of the second light emission layer.

7. The organic EL device according to claim 1, wherein the exciton block layer disposed between the second light emission layer and the third light emission layer has a larger band gap than a band gap of the third light emission layer.

8. An organic EL device comprising:
an insulative film;
a first pixel electrode and a second pixel electrode which are disposed on the insulative film;
a first light emission layer commonly disposed above the first pixel electrode and the second pixel electrode;
a second light emission layer disposed above the first light emission layer;
a counter-electrode disposed above the second light emission layer; and
an exciton block layer disposed between the first light emission layer and the second light emission layer.

9. The organic EL device according to claim 8, wherein the first light emission layer and the second light emission layer include a metal complex compound.

10. The organic EL device according to claim 8, wherein the first light emission layer disposed between the first pixel electrode and the counter-electrode includes an optically quenched dopant material.

11. The organic EL device according to claim 8, wherein the first light emission layer has a first band gap, the second light emission layer has a second band gap which is larger than the first band gap, and the exciton block layer has a third band gap which is larger than the second band gap.

12. A method of manufacturing an organic EL device, comprising:
forming a first pixel electrode and a second pixel electrode on an insulative film;
forming a first light emission layer commonly above the first pixel electrode and the second pixel electrode;
forming an exciton block layer above the first light emission layer;
forming a second light emission layer above the exciton block layer; and
forming a counter-electrode above the second light emission layer.

13. The method according to claim 12, further comprising exposing the first light emission layer, which is disposed above the first pixel electrode, at a time after the formation of the first light emission layer and before the formation of the exciton block layer.

14. The method according to claim 12, further comprising exposing the first light emission layer, which is disposed above the first pixel electrode, at a time after the formation of the exciton block layer and before the formation of the second light emission layer.

15. The method according to claim 12, further comprising exposing the first light emission layer, which is disposed above the first pixel electrode, at a time after the formation of the first light emission layer and before the formation of the counter-electrode.

16. The method according to claim 12, wherein the exciton block layer is formed of a material having a third band gap which is larger than a first band gap of the first light emission layer and a second band gap of the second light emission layer.

17. The method according to claim 12, wherein the first light emission layer and the second light emission layer are formed of a material including a metal complex compound.

18. A method of manufacturing an organic EL device, comprising:
forming first to third pixel electrodes on an insulative film;
forming a first light emission layer commonly above the first to third pixel electrodes;
forming a second light emission layer above the first light emission layer;
forming a third light emission layer above the second light emission layer;
forming a counter-electrode above the third light emission layer; and
forming an exciton block layer at least between the first light emission layer and the second light emission layer or between the second light emission layer and the third light emission layer.

19. The method according to claim 18, further comprising:
exposing the first light emission layer which is disposed above the second pixel electrode and the third pixel electrode; and
exposing the second light emission layer which is disposed above the third pixel electrode.

20. The method according to claim 18, further comprising:
exposing the first light emission layer which is disposed above the second pixel electrode; and
exposing the first light emission layer and the second light emission layer, which are disposed above the third pixel electrode.
